(19) United States
(12) Patent Application Publication
(10) Pub. No.: US 2026/0354285 A1
(43) Pub. Date: Nov. 5, 2026

(54) CHIP PACKAGE WITH REDISTRIBUTION LAYER MODULES FOR DIE INTERCONNECTIONS AND METHOD

(71) Applicant: Micron Technology, Inc., Boise, ID (US)

(72) Inventor: Jungbae LEE, Meridian, ID (US)

(21) Appl. No.: 19/539,820

(22) Filed: Feb. 13, 2026

Related U.S. Application Data
(60) Provisional application No. 63/789,506, filed on Apr. 16, 2025.

(51) Int. Cl. H10W 90/00; H10B 80/00; H10W 70/60; H10W 74/00; H10W 90/24

(52) U.S. Cl. CPC H10W 90/401; H10B 80/00; H10W 70/616; H10W 74/00; H10W 90/24

(57) ABSTRACT

Implementations described herein relate to various semiconductor device assemblies. In some implementations, a semiconductor device assembly includes a circuit substrate comprising a first substrate surface and a second substrate surface arranged opposite to the first substrate surface; a die stack comprising a plurality of dies arranged on the first substrate surface in a first shingle stack configuration, wherein each die of the plurality of dies has an upper die surface with an exposed portion that includes one or more exposed bond pads; and a redistribution layer (RDL) module stack comprising a plurality of RDL modules arranged on the first substrate surface in a second shingle stack configuration that corresponds to the first shingle stack configuration. The RDL module stack is configured to electrically couple each die of the plurality of dies to the circuit substrate.

### CROSS-REFERENCE TO RELATED APPLICATION

This Patent Application claims priority to U.S. Provisional Patent Application No. 63/789,506, filed on Apr. 16, 2025, entitled “CHIP PACKAGE WITH REDISTRIBUTION LAYER MODULES FOR DIE INTERCONNECTIONS AND METHOD,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a chip package with redistribution layer (RDL) modules for die interconnections.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example apparatus that may be manufactured using techniques described herein.

FIGS. 3A-3G are cross-sectional views showing formation of a semiconductor device assembly at example process stages of an example process of forming the semiconductor device assembly.

### DETAILED DESCRIPTION

In the field of semiconductor packaging and assembly, electrical interconnections between semiconductor dies and a circuit substrate, such as a printed circuit board (PCB), are important for the manufacturing of semiconductor device assemblies (e.g., die packages) and the functionality of electronic devices. The circuit substate may be referred to as a chip carrier or a package substrate. Traditionally, wirebond methods have been employed to create these interconnections. This process involves creating a physical connection between each die and the substrate by bonding fine wires from die pads to substrate pads. However, wirebonding can be exceedingly time-consuming when there are a large number of input/output (I/O) connections, as each wire must be connected individually. Furthermore, the physical dimensions of the wires impose limitations on how closely the wires can be spaced, which restricts the bond wire pitch and, consequently, a maximum number of I/O connections that can be accommodated. Wirebonding also has inherent issues such as the risk of wire sweep during molding, which can lead to short circuits, and the need for sufficient clearance above the wires to prevent interference with subsequent packaging layers, which leads to larger package sizes. Additionally, the length of the wirebonds can adversely impact signal performance due to increased electrical path length, which can degrade signal integrity and speed. The combination of these factors -- time-intensive process, limitation on I/O density, risk of electrical shorts, cost considerations, and suboptimal signal performance -- presents a technical problem in the semiconductor packaging industry for creating die-to-substrate interconnections and manufacturing semiconductor device assemblies.

Some implementations described herein provide a semiconductor device assembly that employs a method for electrically connecting multiple semiconductor dies to a circuit substrate. For example, the semiconductor device assembly may include a circuit substrate and a die stack with multiple dies arranged in a shingle-stack configuration, where each die has an upper surface with exposed bond pads. A redistribution layer (RDL) module stack, including multiple RDL modules arranged in a corresponding shingle-stack configuration, is configured to electrically couple each die to the circuit substrate. In some implementations, one or more RDL modules may be arranged in an alternative configuration for connecting shingle-stacked dies. In some implementations, an RDL module stack may be used for single die configurations (e.g., for connecting a single die (a non-stacked die) to the circuit substrate).

In some aspects, the RDL modules are single-layer structures that are mechanically bonded to the upper surfaces of the dies using electrical interconnects, such as conductive bumps or thermocompression interconnects. The RDL modules are designed with conductive paths to transmit data and/or power signals between the circuit substrate and the dies. Additionally, the RDL module stack is laterally offset from the die stack to match the shingle-stack configuration of the dies, ensuring that each exposed bond pad is mechanically and electrically coupled to the RDL module stack.

In this way, the one or more implementations provide an alternative interconnection method to traditional wirebonding, addressing the technical challenges associated with wirebond packaging structures. The RDL module interconnection method may significantly reduce a bonding time for each die interconnection, with times as fast as 3 to 5 seconds, which is much faster than traditional wirebonding methods, thereby conserving manufacturing process resources.

Furthermore, the RDL module interconnection allows for finer pitch interconnections, enabling a higher I/O count than wirebonding. Moreover, when compared to traditional wirebonding methods, the RDL module stack enables shorter electrical signal paths between dies and the circuit substrate. As a result, the RDL module interconnection may lead to enhanced signal integrity due to shorter electrical signal paths and reduced parasitic inductances. The RDL module interconnection may reduce or eliminate the risk of electrical shorts that would otherwise be a concern with traditional wirebonding methods. Moreover, when compared to traditional wirebonding methods, the RDL module stack enables smaller package profiles due to reduced package height when compared to package height in packages in which wirebonds are used. Additionally, there is a substantial increase in units per hour (UPH), or a quantity of die capable of being produced per hour, directly translating to improved production throughput and efficiency. These technical advancements facilitate a reduction in production costs, an increase in packaging density, and an improvement in the overall quality and reliability of semiconductor device assemblies. In this way, the quality and/or reliability of the semiconductor device assembly is improved. In summary, one or more RDL modules may be used to provide RDL module interconnections between one or more dies and the circuit substrate for faster assembly times, improved die-substrate signal connections, enhanced reliability, and smaller die profiles.

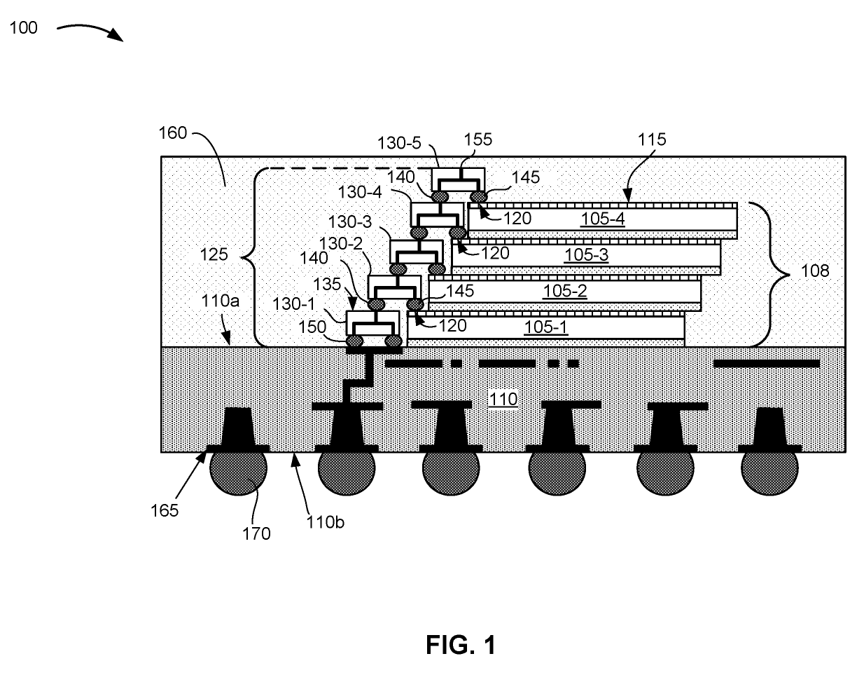

FIG. 1 is a diagram of an example apparatus 100 that may be manufactured using techniques described herein. The apparatus 100 may include any type of device or system that includes one or more semiconductor dies 105 (sometimes called a dies or a chips). For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, a die package, a chip package, an assembly, a semiconductor device assembly, or an integrated assembly.

As shown in FIG. 1, the apparatus 100 may include a plurality of semiconductor dies 105-1, 105-2, 105-3, and 105-4 (e.g., collectively referred to as dies 105) arranged vertically in a die stack 108. Thus, the dies 105 may be stacked on top of each other to reduce a footprint of the apparatus 100. The dies 105 may be disposed on a circuit substrate 110. The circuit substrate 110 may be a PCB, an RDL, or another type of chip carrier or package substrate. For example, the circuit substrate 110 may have a first substrate surface 110a (e.g., an upper substrate surface) and a second substrate surface 110b (e.g., a lower substrate surface) arranged opposite to the first substrate surface 110a, and the dies 105 may be arranged on the first substrate surface 110a.

Each die 105 may include any type of circuit, such as an analog circuit, a digital circuit, a controller (e.g., a microcontroller), a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). Although the apparatus 100 is shown as including four dies 105 as an example, the apparatus 100 may include a different number of semiconductor dies 105, such as two or more semiconductor dies arranged in a die stack. In some implementations, the apparatus 100 may include a single die (e.g., die 105-1) (e.g., a stand-alone die) that is not arranged in a die stack. In some implementations, the apparatus 100 may include multiple integrated circuits, such as multiple laterally-separated semiconductor dies or multiple laterally-separated die stacks.

In some implementations, a spacer may be present between semiconductor dies 105-1, 105-2, 105-3, and 105-4 that are adjacent to one another in the stack to enable electrical separation and heat dissipation. A first semiconductor die 105-1 (sometimes called a bottom die or a base die) may be disposed on the first substrate surface 110a (e.g., proximate to the circuit substrate 110), a second semiconductor die 105-2 may be disposed on the first semiconductor die 105-1, and so on. The uppermost die (e.g., semiconductor die 105-4), furthest from the circuit substrate 110, may be referred to as a top die or an upper die. Thus, the first semiconductor die 105-1 may be coupled adjacent to the first substrate surface 110a, and the semiconductor die 105-4 may be arranged furthest from the first substrate surface 110a among the plurality of dies.

The semiconductor dies 105-1, 105-2, 105-3, and 105-4 may be arranged and connected in a first shingle-stack configuration to form a shingle stack. In the first shingle-stack configuration, die edges of the semiconductor dies 105-1, 105-2, 105-3, and 105-4 are not aligned, but are instead laterally offset from each other. Thus, each subsequent die (e.g., a higher die) of the die stack 108 is laterally offset from a previous die (e.g., a lower die) of the die stack 108. For example, the first shingle stack configuration may resemble a staircase. The first shingle-stack configuration, with die edges that are offset, provides space for electrical connections near the edges of the semiconductor dies 105-1, 105-2, 105-3, and 105-4. Thus, each semiconductor die 105 may have an upper die surface 115 with an exposed portion that includes one or more exposed bond pads 120 that are to be electrically connected to the circuit substrate 110. Here, “exposed” means exposed during assembly and does not necessarily mean exposed to an environment after encapsulation with a package casing. For example, the exposed bond pads 120 may be exposed during assembly for RDL interconnection, and subsequently encapsulated by the package casing. In some examples, a surface at which die interconnections, such as bond pads, are provided may be referred to as an “interconnection side.” In this example, the interconnection sides of the dies 105 (e.g., the upper die surfaces 115) face away from the first substrate surface 110a

The apparatus 100 may include an RDL module stack 125 comprising a plurality of RDL modules 130-1, 130-2, 130-3, 130-4, and 130-5 (e.g., collectively referred to as RDL modules 130) arranged on the first substrate surface 110a in a second shingle stack configuration that corresponds to the first shingle stack configuration of the dies 105. For example, module edges of the RDL modules 130 of are not aligned, but are instead laterally offset from each other in similar stepped configuration as the first shingle stack configuration of the dies 105. Thus, each subsequent RDL module (e.g., a higher RDL module) of the RDL module stack 125 is laterally offset from a previous die (e.g., a lower RDL module) of the RDL module stack 125. For example, the second shingle stack configuration may resemble a staircase that is sufficiently proximate to the die stack 108 for being connected to the dies 105. Thus, the RDL module stack 125 is configured to electrically couple each die 105 to the circuit substrate 110.

A first RDL module 130-1 (sometimes called a bottom RDL module or a base RDL module) may be disposed on the first substrate surface 110a (e.g., proximate to the circuit substrate 110), a second RDL module 130-2 may be disposed on the first RDL module 130-1, and so on. The uppermost RDL module 130 (e.g., RDL module 130-5), furthest from the circuit substrate 110, may be referred to as a top RDL module 130 or an upper RDL module 130. Each RDL module 130 may be a single RDL. For example, each RDL module 130 may be a single substrate layer with one or more conductive paths or interconnects routed through the single substrate layer.

The plurality of dies 105-1, 105-2, 105-3, and 105-4 is N dies, where N is an integer greater than one to form the die stack 108. Thus, a quantity of dies 105 is N (e.g., 4). The plurality of RDL modules 130-1, 130-2, 130-3, 130-4, and 130-5 is N+1 RDL modules. Thus, a quantity of RDL modules 130 is N+1 (e.g., 5). The base RDL module 130-1 is mechanically and electrically coupled to the first substrate surface 110a. In addition, two or more subsequent RDL modules 130 (e.g., RDL modules 130-2, 130-3, 130-4, and 130-5) are respectively coupled to the plurality of dies 105.

As described above, the semiconductor die 105-4 may be the top die. In the example shown in FIG. 1, the first RDL module 130-1 may be coupled adjacent to the first substrate surface 110a. Each RDL module 130, excluding the base RDL module 130-1, is mechanically bonded to an upper die surface 115 of a respective die 105 by an electrical interconnect for providing an electrical signal to the respective die 105. For example, RDL module 130-2 is coupled the upper die surface 115 of die 105-1, RDL module 130-3 is coupled the upper die surface 115 of die 105-2, RDL module 130-4 is coupled the upper die surface 115 of die 105-3, and RDL module 130-5 is coupled the upper die surface 115 of die 105-4. Thus, the top RDL module 130 (e.g., the RDL module 130-5) may be coupled to the upper die surface 115 of the top die 105-4. In addition, each RDL module 130, excluding the top RDL module 130-5, includes an upper module surface 135 that may be substantially planar with an upper die surface 115 of a respective die 105 to provide quality electrical connections with a least amount of stress imposed on the dies 105.

The apparatus 100 may include a plurality of conductive module-to-module interconnects 140 arranged between adjacent RDL modules 130 for mechanical and electrical coupling of the adjacent RDL modules 130. Additionally, the apparatus 100 may include a plurality of conductive module-to-die interconnects 145 for mechanical and electrical coupling of each RDL module 130 (e.g., each subsequent RDL module 130-2, 130-3, 130-4, and 130-5) to a respective die 105. The apparatus 100 may include a plurality of conductive module-to-substrate interconnects 150 for mechanical and electrical coupling of the bottom RDL module 130-1 to the circuit substrate 110.

The plurality of conductive module-to-module interconnects 140, the plurality of conductive module-to-die interconnects 145, and the plurality of conductive module-to-substrate interconnects 150 may be conductive bumps and/or thermocompression interconnects.

Each subsequent die 105 is laterally offset from a previous die 105 such that each exposed portion is exposed for RDL connection. As a result, each exposed bond pad 120 of the one or more exposed bonds is mechanically and electrically coupled to the RDL module stack 125. As described above, each RDL module 130, excluding the base RDL module 130-1, is mechanically bonded to an upper die surface 115 of a respective die 105 by an electrical interconnect for providing an electrical signal to the respective die 105. Each subsequent RDL module (e.g., RDL module 130-2, 130-3, 130-4, and 130-5) is laterally offset from a previous RDL module 130 such that the subsequent RDL module is mechanically and electrically coupled to the one or more exposed bond pads 120 of a respective die 105. Thus, the first shingle stack configuration of the die stack 108 and the second shingle stack configuration of the RDL module stack 125 enable the RDL module stack 125 to electrically couple each die 105 to the circuit substrate 110.

Each RDL module 130 may include one or more conductive paths 155 for transmitting data signals between the circuit substrate 110 and the dies 105. Additionally, or alternatively, the conductive paths 155 may be used for transmitting power signals between the circuit substrate 110 and the dies 105. In some implementations, the dies 105 are memory dies (e.g., DRAM dies) configured to store data according to write operations and output data according to read operations. The RDL modules 130 may transmit I/O data signals between the circuit substrate 110 and the dies 105 according to the write operations and the read operations.

Although FIG. 1 shows the semiconductor dies 105-1, 105-2, 105-3, and 105-4 stacked in a shingle stack (e.g., with die edges that are not aligned), in some implementations, the semiconductor dies 105-1, 105-2, 105-3, and 105-4 may be stacked in a different arrangement, such as a straight stack (e.g., with aligned die edges). For example, in a straight stack, the stacked semiconductor dies 105-1, 105-2, 105-3, and 105-4 may include three-dimensional electrical interconnects, such as through- silicon vias (TSVs), to route electrical signals between the semiconductor dies 105-1, 105-2, 105-3, and 105-4. In this example, the RDL modules 130-1, 130-2, 130-3, and 130-4 may also be arranged in a straight stack to substantially match a height of the straight stack of dies, and the top RDL module 130-5 may be laterally offset from the other RDL modules 130-1, 130-2, 130-3, and 130-4 for coupling the top RDL module 130-5 to the upper die surface 115 of the top die 105-4. Thus, the stacked semiconductor dies 105-1, 105-2, 105-3, and 105-4 may be connected by a combination of the RDL module stack 125 and the TSVs.

The apparatus 100 may include a package casing 160 that protects internal components of the apparatus 100 (e.g., die stack 108 and the RDL module stack 125) from damage and environmental elements (e.g., particles) that can lead to malfunction of the apparatus 100. The package casing 160 may fully encapsulate the die stack 108 and the RDL module stack 125 to provide optimal protection to the die stack 108 and the RDL module stack 125. The package casing 160 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board, such as a PCB. For example, the circuit substrate 110 may be disposed on the circuit board such that electrical contacts 165 (e.g., bond pads) of the circuit substrate 110 are electrically connected to electrical contacts (e.g., bond pads) of the circuit board.

In some implementations, the circuit substrate 110 may be mounted on the circuit board using a plurality of conductive interconnect structures 170 (e.g., solder balls arranged in a ball grid array), which may be melted to form a physical and electrical connection between the circuit substrate 110 and the circuit board. Additionally, or alternatively, the circuit substrate 110 may be mounted on and/or electrically connected to the circuit board using another type of conductive connector, such as pins or leads. Thus, the plurality of conductive interconnect structures 170 are coupled to the second substrate surface 110b, and the plurality of conductive interconnect structures 170 are electrically coupled to the plurality of RDL modules 130 by the circuit substrate 110 (e.g., by one or more conductive paths/traces routed through the circuit substrate 110). The interconnections between the die stack 108, the RDL module stack 125, the circuit substrate 110, and the circuit board enable the dies 105 to receive signals from and transmit signals to other components of the apparatus 100 and/or the higher level system.

In some implementations, the apparatus 100 may include a single die (e.g., die 105-1) (e.g., a stand-alone die) that is not arranged in a die stack. In this case, N = 1 and a quantity of RDL modules is N+1 (e.g., 2). Thus, the apparatus 100 may include a die 105-1 arranged on the first substrate surface 110a, wherein the die has an upper die surface 115 with an edge portion that includes one or more exposed bond pads 120; an RDL module stack 125 comprising a plurality of RDL modules 130 (e.g., RDL modules 130-1 and 130-2) arranged on the first substrate surface 110a in a shingle stack configuration, the RDL module stack 125 being configured to electrically couple the die 105-1 to the circuit substrate 110. The plurality of RDL modules 130-1 and 130-2 includes an RDL module 130-2 arranged on the edge portion of the die 105-1 and coupled to the one or more exposed bond pads 120 of the die 105-1.

Additionally, the apparatus 100 may include a package casing 160 disposed over the first substrate surface 110a to encapsulate the die 105-1 and the plurality of RDL modules 130-1 and 130-2. The apparatus 100 may include a plurality of conductive interconnect structures 170 coupled to the second substrate surface 110b such that the plurality of conductive interconnect structures 170 are electrically coupled to the plurality of RDL modules 130-1 and 130-2 by the circuit substrate 110.

During manufacturing, the die stack 108 may be formed first on the circuit substrate 110. After the die stack 108 is formed, the RDL module stack 125 may be formed in iterative steps, with respective conductive module-to-module interconnects 140 and respective conductive module-to-die interconnects 145 being formed after each RDL module 130 is disposed. The next RDL module 130 may then be disposed on the respective conductive module-to-module interconnects 140 and respective conductive module-to-die interconnects 145 of the previous step.

The RDL module stack 125 provides an alternative interconnection method to traditional wirebonding, addressing the technical challenges associated with wirebond packaging structures. The RDL module stack 125 may significantly reduce a bonding time for each die interconnection, with times as fast as 3 to 5 seconds, which is much faster than traditional wirebonding methods, thereby conserving manufacturing process resources and increasing units per hour in manufacturing semiconductor device assemblies.

Furthermore, the RDL module stack 125 allows for finer pitch interconnections, enabling a higher I/O count than wirebonding. Moreover, when compared to traditional wirebonding methods, the RDL module stack 125 enables shorter electrical signal paths between dies and the circuit substrate. As a result, the RDL module stack 125 may lead to enhanced signal integrity due to shorter electrical signal paths and reduced parasitic inductances. The RDL module stack 125 may reduce or eliminate the risk of electrical shorts that would otherwise be a concern with traditional wirebonding methods. Moreover, when compared to traditional wirebonding methods, the RDL module stack 125 may enable smaller package profiles due to reduced package height when compared to package height in packages in which wirebonds are used. In summary, the RDL module stack 125 may be used to provide RDL module interconnections between one or more dies 105 and the circuit substrate 110 for faster assembly times, improved die-substrate signal connections, enhanced reliability, and smaller die profiles.

As indicated above, FIG. 1 is provided as an example. Other examples may differ from what is described with regard to FIG. 1.

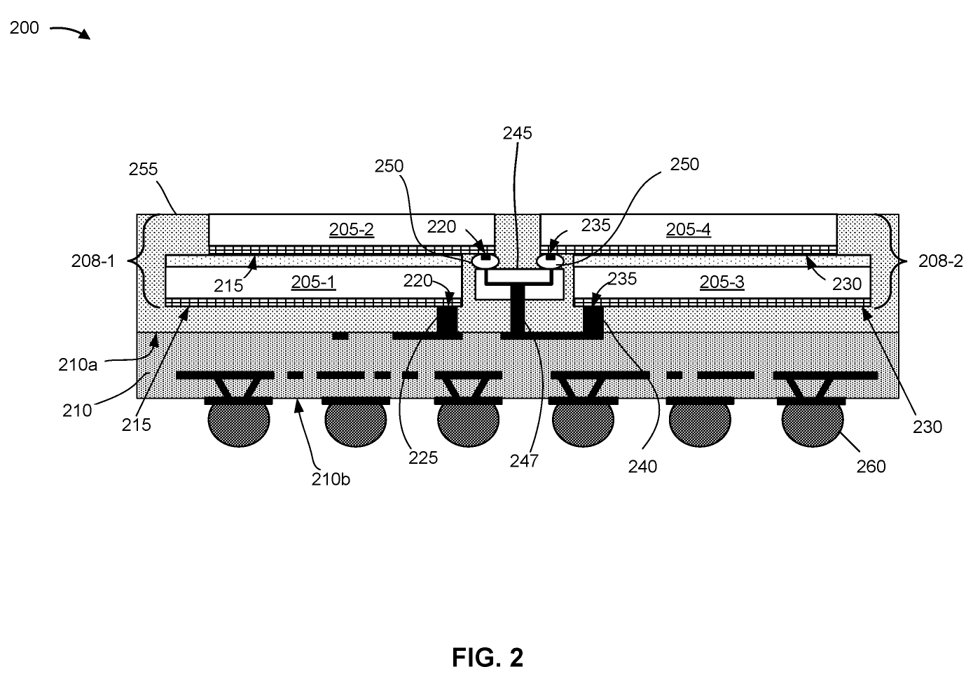

FIG. 2 is a diagram of an example apparatus 200 that may be manufactured using techniques described herein. The apparatus 200 may be referred to as a semiconductor package, a die package, a chip package, an assembly, a semiconductor device assembly, or an integrated assembly. In some implementations, the apparatus 200 may be a quad die package (QDP).

As shown in FIG. 2, the apparatus 200 may include a plurality of semiconductor dies 205-1, 205-2, 205-3, and 205-4 (e.g., collectively referred to as dies 205) arranged over a circuit substrate 210. The circuit substrate 210 may have a first substrate surface 210a (e.g., an upper substrate surface) and a second substrate surface 210b (e.g., a lower substrate surface) arranged opposite to the first substrate surface 210a, and the dies 205 may be arranged over the first substrate surface 210a.

The semiconductor dies 205-1, 205-2, 205-3, and 205-4 may be arranged in two die stacks. For example, the apparatus 200 may include a first die stack 208-1 that includes a plurality of first dies 205-1 and 205-2 arranged over the first substrate surface 210a in a first shingle stack configuration, and second die stack 208-2 that includes a plurality of second dies 205-3 and 205-4 arranged over the first substrate surface 210a in a second shingle stack configuration. The first shingle stack configuration and the second shingle stack configuration may shift toward each other such a distance between the first die stack 208-1 and the second die stack 208-2 decreases for each subsequent level of die. In other words, the first die stack 208-1 and the second die stack 208-2 are furthest apart for dies closest to the circuit substrate 210, and the first die stack 208-1 and the second die stack 208-2 are closest for dies furthest from the circuit substrate 210. Thus, the first shingle stack configuration and the second shingle stack configuration are reverse shingle stack configurations.

Each first die 205-1 and 205-2 of the plurality of first dies has a first interconnect side 215 facing the first substrate surface 210a. The first interconnect side 215 includes one or more first conductive die interconnect structures 220 for being electrically connected to the circuit substrate 210. The first conductive die interconnect structures 220 may include bond pads and/or conductive posts. The plurality of first dies 205-1 and 205-2 includes a first base die 205-1, electrically coupled to the circuit substrate 110 by a first die-to-substrate interconnection 225 that includes one or more first conductive die interconnect structures 220 of the first base die 205-1. The plurality of first dies 205-1 and 205-2 also includes a first subsequent die 205-2 arranged on the first base die 205-2.

Each second die 205-3 and 205-4 of the plurality of second dies has a second interconnect side 230 facing the first substrate surface 210a. The second interconnect side 230 includes one or more second conductive die interconnect structures 235 for being electrically connected to the circuit substrate 210. The second conductive die interconnect structures 235 may include bond pads and/or conductive posts. The plurality of second dies 205-3 and 205-4 includes a second base die 205-3, electrically coupled to the circuit substrate 110 by a second die-to-substrate interconnection 240 that includes one or more second conductive die interconnect structures 235 of the second base die 205-1. The plurality of second dies 205-1 and 205-2 also includes a second subsequent die 205-4 arranged on the second base die 205-3.

The apparatus 200 further includes an RDL module 245 arranged over the first substrate surface 210a. The RDL module 245 is also arranged laterally between the first base die 205-1 and the second base die 205-3 such that the RDL module 245 is capable of making electrical connections to the first subsequent die 205-2 and the second subsequent die 205-4. The RDL module 245 may be a single RDL with a single substrate layer that includes one or more conductive paths or interconnects routed through the single substrate layer. In some implementations, one or more additional RDL modules 245 may be arranged in an RDL module stack to accommodate die stacks with three or more dies.

The RDL module 245 may be coupled to one or more first conductive die interconnect structures 220 of the first subsequent die 205-2 for electrically coupling the first subsequent die 205-2 to the circuit substrate 110. Additionally, the RDL module 245 may be coupled to one or more second conductive die interconnect structures 235 of the second subsequent die 205-4 for electrically coupling the second subsequent die 205-4 to the circuit substrate 110. The apparatus 200 may include one or more conductive module-to-substrate interconnect structures 247 for mechanical and electrical coupling of the RDL module 245 to the circuit substrate 210.

The apparatus 200 may further include a plurality of conductive module-to-die interconnects 250 for mechanical and electrical coupling of the RDL module 245 to the one or more first conductive die interconnect structures 220 of the first subsequent die 205-2 and to the one or more second conductive die interconnect structures 235 of the second subsequent die 205-4. The plurality of conductive module-to-die interconnects 250 may be conductive bumps arranged on the RDL module 245. In some implementations, the RDL module 245 is electrically coupled to the first base die 205-1 and the second base die 205-3 by the circuit substrate. Thus, the RDL module 245 may provide electrical connections to the first subsequent die 205-2 and the second subsequent die 205-4, or all dies 205-1, 205-2, 205-3, and 205-4.

In some implementations, the plurality of first dies 205-1 and 205-2 and the plurality of second dies 205-3 and 205-4 are memory dies configured to store data according to write operations and output data according to read operations. The RDL module 245 may be configured to transmit I/O data signals between the circuit substrate 210 and the plurality of first dies 205-1 and 205-2 and between the circuit substrate 210 and the plurality of second dies 205-3 and 205-4 according to the write operations and the read operations.

The apparatus 200 may further include a package casing 255 disposed over the first substrate surface 210a that protects internal components of the apparatus 200 (e.g., die stacks 208-1 and 208-2, RDL module 245, and conductive interconnections of the RDL module stack 125) from damage and environmental elements. The package casing 255 may partially or fully encapsulate the die stacks 208-1 and 208-2. For example, in some cases, a top of the package casing 255 may be planar with the upper die surfaces of the first subsequent die 205-2 and the second subsequent die 205-4 to maintain a low- package profile. In other cases, the package casing 255 extend over the upper die surfaces of the first subsequent die 205-2 and the second subsequent die 205-4 to fully encapsulate the die stacks 208-1 and 208-2.

The apparatus 200 may further include a plurality of conductive interconnect structures 260 coupled to the second substrate surface 210b. The plurality of conductive interconnect structures 260 are electrically coupled to the RDL module 245 by the circuit substrate 210.

The RDL module 245 provides an alternative interconnection method to traditional wirebonding, addressing the technical challenges associated with wirebond packaging structures. The RDL module 245 may significantly reduce a bonding time for each die interconnection, with times as fast as 3 to 5 seconds, which is much faster than traditional wirebonding methods, thereby conserving manufacturing process resources and increasing units per hour in manufacturing semiconductor device assemblies.

Furthermore, the RDL module 245 allows for finer pitch interconnections, enabling a higher I/O count than wirebonding. Moreover, when compared to traditional wirebonding methods, the RDL module 245 enables shorter electrical signal paths between dies and the circuit substrate. As a result, the RDL module 245 may lead to enhanced signal integrity due to shorter electrical signal paths and reduced parasitic inductances. The RDL module 245 may reduce or eliminate the risk of electrical shorts that would otherwise be a concern with traditional wirebonding methods. Moreover, when compared to traditional wirebonding methods, the RDL module 245 may enable smaller package profiles due to reduced package height when compared to package height in packages in which wirebonds are used. In summary, the RDL module 245 may be used to provide RDL module interconnections between one or more dies 205 and the circuit substrate 210 for faster assembly times, improved die-substrate signal connections, enhanced reliability, and smaller die profiles.

As indicated above, FIG. 2 is provided as an example. Other examples may differ from what is described with regard to FIG. 2.

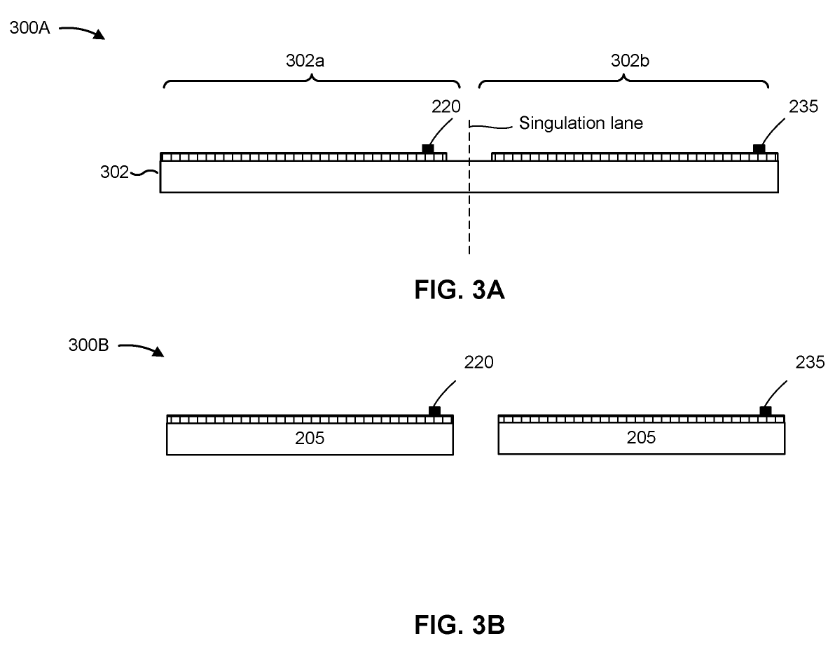

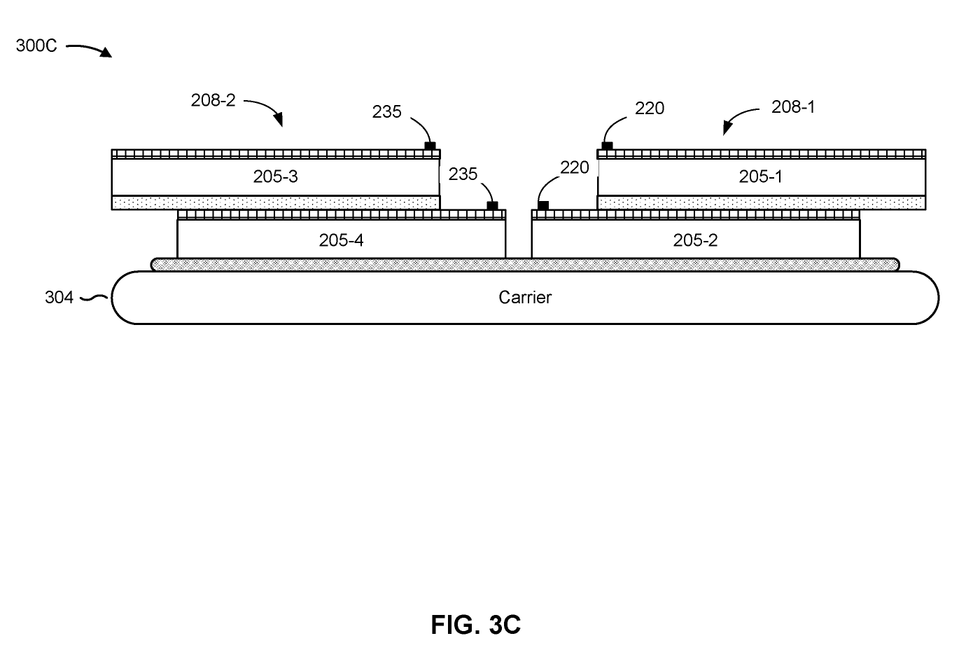

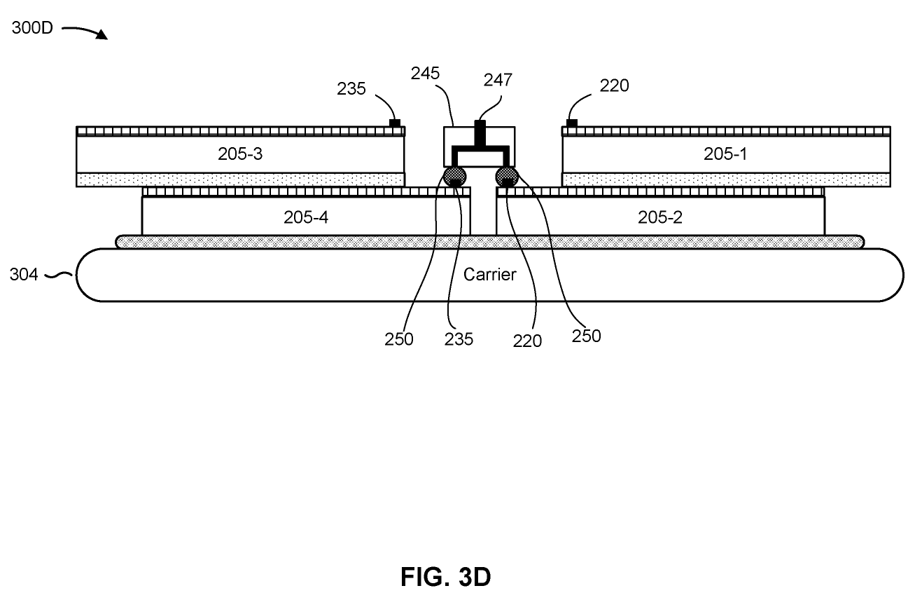

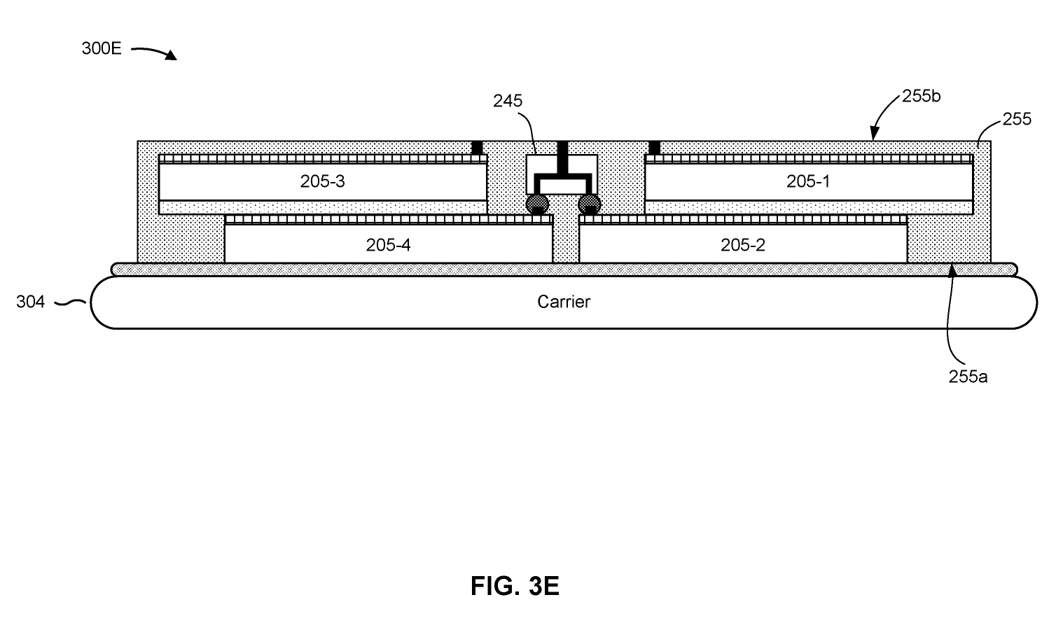

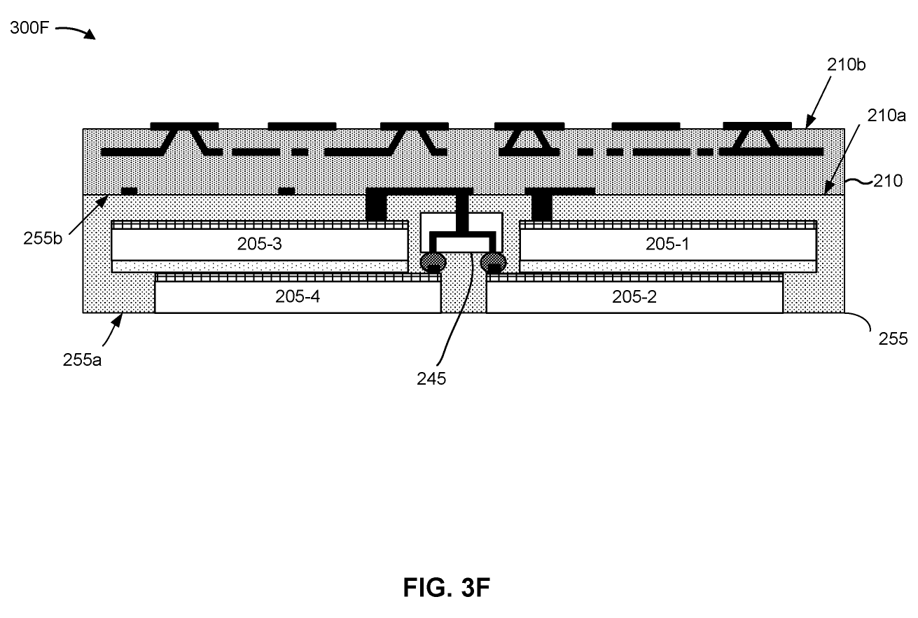

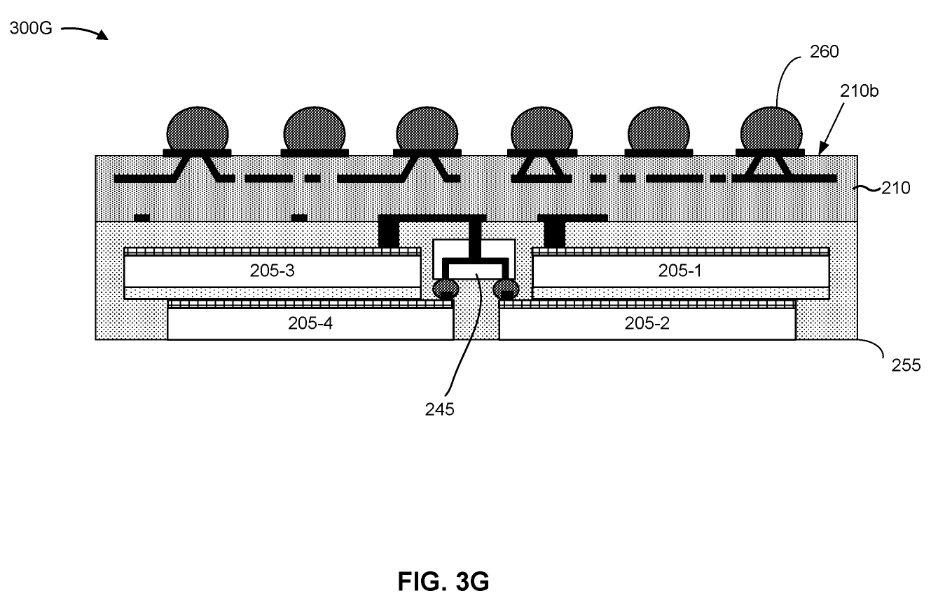

FIGS. 3A-3G are cross-sectional views showing formation of a semiconductor device assembly at example process stages of an example process of forming the semiconductor device assembly. In some implementations, the semiconductor device assembly may be semiconductor package (sometimes called die or chip packages) that include one or more dies. In some implementations, the example process described below in connection with FIGS. 3A-3G may correspond to a method of manufacturing a semiconductor device assembly that includes two or more dies arranged in a vertical stack (e.g., a die stack). The process may be used to form apparatus 100, or apparatus 200, and/or another apparatus described elsewhere herein. In some implementations, one or more process stages described below in connection with FIGS. 3A-3G may be performed by various semiconductor manufacturing equipment. However, the process described below is an example, and other example processes may be used to form the structure, an integrated assembly that includes the structure, and/or one or more parts of the structure and/or the integrated assembly.

As shown in FIG. 3A, the process may include a process stage 300A that includes providing a wafer 302 having a first die region 302a and a second die region 302b delineated by a singulation lane, and disposing conductive die interconnect structures (e.g., first conductive die interconnect structures 220 and/or second conductive die interconnect structures 235) on an interconnect side of the wafer 302 for each die region 302a and 302b. In some implementations, the conductive die interconnect structures may include bond pads and/or conductive posts, such as copper posts.

As shown in FIG. 3B, the process may include a process stage 300B that includes separating the wafer 302 into dies (e.g., dies 205) by one or more dicing techniques. For example, the first die region 302a and the second die region 302b may be separated at the singulation lane to form two dies 205. While only two die regions/two dies are shown, three or more dies may be formed from wafer 302.

As shown in FIG. 3C, the process may include a process stage 300C that includes arranging a plurality of first dies 205-1 and 205-2 on a carrier 304 in a first shingle stack configuration to form a first die stack 208-1, and arranging a plurality of second dies 205-3 and 205-4 on the carrier in a second shingle stack configuration to form a second die stack 208-2. Each first die 205 of the plurality of first dies 205-1 and 205-2 has a first interconnect side facing away from the carrier 304, the first interconnect side comprising one or more first conductive die interconnect structures 220. Additionally, each second die 205 of the plurality of second dies 205-3 and 205-4 has a second interconnect side facing away from the carrier 304, the second interconnect side comprising one or more second conductive die interconnect structures 235.

As shown in FIG. 3D, the process may include a process stage 300D that includes arranging an RDL module 245 on a corresponding first die 205-2 of the plurality of first dies 205-1 and 205-2 and on a corresponding second die 205-4 of the plurality of second dies 205-3 and 205-4. Thus, the RDL module 245 may be formed laterally between the first die stack 208-1 and the second die stack 208-2. The RDL module 245 may be electrically coupled to one or more first conductive die interconnect structures 220 of the corresponding first die 205-2, and may be electrically coupled to one or more second conductive die interconnect structures 235 of the corresponding second die 205-4.

The process stage 300D may also include forming one or more conductive module-to-substrate interconnect structures 247 on the RDL module 245.

The process stage 300D may also include forming a plurality of conductive module-to-die interconnects 250 for mechanical and electrical coupling of the RDL module 245 to the one or more first conductive die interconnect structures 220 of the first subsequent die 205-2 and to the one or more second conductive die interconnect structures 235 of the second subsequent die 205-4.

As shown in FIG. 3E, the process may include a process stage 300E that includes encapsulating the plurality of first dies 205-1 and 205-2, the plurality of second dies 205-3 and 205-4, and the RDL module 245 in a package casing 255. The package case 255 includes a first side 255a arranged on the carrier and second side 255b opposite to the first side 255a.

The package casing 255 may fill areas or gaps between the dies 205 and the RDL module 245. The package casing 255 may be formed over the dies 205-3 and 205-1 such that the second side 255b functions as a mounting surface. The package casing 255 may partially encapsulate the dies 205-2 and 205-4 such that the first side 255a is planar with carrier-side surfaces of the dies 205-2 and 205-4.

As shown in FIG. 3F, the process may include a process stage 300F that includes removing the carrier 304. The process stage 300F may also include coupling the plurality of first dies 205-1 and 205-2, the plurality of second dies 205-3 and 205-4, and the RDL module 245 to a first substrate surface 210a of a circuit substrate 210 such that the second side 255b (e.g., the mounting surface) of the package casing 255 is coupled or mounted to the first substrate surface 210a of the circuit substrate 210. In addition, the module-to-substrate interconnect structures 247, the first conductive die interconnect structures 220, and the second conductive die interconnect structures 235 are electrically coupled to the circuit substrate 210. Thus, the circuit substrate 210 is electrically coupled to the corresponding second die 205-4 and the corresponding first die 205-2 by the RDL module 245.

As shown in FIG. 3G, the process may include a process stage 300G that includes disposing a plurality of conductive interconnect structures 260 on the second substrate surface 210b. For example, the plurality of conductive interconnect structures 260 may be disposed on the second substrate surface 210b using a ball attach process. One or more conductive interconnect structures 260 are electrically coupled to the corresponding second die 205-4 and the corresponding first die 205-2 by the circuit substrate 210 and the RDL module 245.

As indicated above, the process steps described in connection with FIGS. 3A-3G are provided as examples. Other examples may differ from what is described with respect to FIGS. 3A-3G. The structures shown in FIG. 3G may be equivalent to structures described elsewhere herein.

In some implementations, a semiconductor device assembly includes a circuit substrate comprising a first substrate surface and a second substrate surface arranged opposite to the first substrate surface; a die stack comprising a plurality of dies arranged on the first substrate surface in a first shingle stack configuration, wherein each die of the plurality of dies has an upper die surface with an exposed portion that includes one or more exposed bond pads; and an RDL module stack comprising a plurality of RDL modules arranged on the first substrate surface in a second shingle stack configuration that corresponds to the first shingle stack configuration, wherein the RDL module stack is configured to electrically couple each die of the plurality of dies to the circuit substrate.

In some implementations, a semiconductor device assembly includes a circuit substrate comprising a first substrate surface and a second substrate surface arranged opposite to the first substrate surface; a die arranged on the first substrate surface, wherein the die has an upper surface with an edge portion that includes one or more bond pads; an RDL module stack comprising a plurality of RDL modules arranged on the first substrate surface in a shingle stack configuration, wherein the RDL module stack is configured to electrically couple the die to the circuit substrate, and wherein the plurality of RDL modules includes an RDL module arranged on the edge portion of the die and coupled to the one or more bond pads; a package casing disposed over the first substrate surface, wherein the package casing encapsulates the die and the plurality of RDL modules; and a plurality of conductive interconnect structures coupled to the second substrate surface, wherein the plurality of conductive interconnect structures are electrically coupled to the plurality of RDL modules by the circuit substrate.

In some implementations, a semiconductor device assembly includes a circuit substrate comprising a first substrate surface and a second substrate surface arranged opposite to the first substrate surface; a first die stack comprising a plurality of first dies arranged over the first substrate surface in a first shingle stack configuration, wherein each first die of the plurality of first dies has a first interconnect side facing the first substrate surface, the first interconnect side comprising one or more first conductive die interconnect structures for being electrically connected to the circuit substrate, wherein the plurality of first dies includes: a first base die, electrically coupled to the circuit substrate by a first die-to-substrate interconnection that includes one or more first conductive die interconnect structures of the first base die; and a first subsequent die arranged on the first base die; and an RDL module arranged over the first substrate surface, wherein the RDL module is coupled to one or more first conductive die interconnect structures of the first subsequent die for electrically coupling the first subsequent die to the circuit substrate.

In some implementations, a method of manufacturing a semiconductor device assembly includes arranging a plurality of first dies on a carrier in a first shingle stack configuration, wherein each first die of the plurality of first dies has a first interconnect side facing away from the carrier, the first interconnect side comprising one or more first conductive die interconnect structures; arranging a plurality of second dies on the carrier in a second shingle stack configuration, wherein each second die of the plurality of second dies has a second interconnect side facing away from the carrier, the second interconnect side comprising one or more second conductive die interconnect structures; arranging an RDL module on a corresponding first die of the plurality of first dies and on a corresponding second die of the plurality of second dies, wherein the RDL module is electrically coupled to one or more first conductive die interconnect structures of the corresponding first die, and wherein the RDL module is electrically coupled to one or more second conductive die interconnect structures of the corresponding second die; encapsulating the plurality of first dies, the plurality of second dies, and the RDL module in a package casing, wherein the package casing includes a first side arranged on the carrier and second side opposite to the first side; removing the carrier; and coupling the plurality of first dies, the plurality of second dies, and the RDL module to a first substrate surface of a circuit substrate such that the second side of the package casing is coupled to the first substrate surface, wherein the circuit substrate is electrically coupled to the corresponding second die and the corresponding first die by the RDL module.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a circuit substrate comprising a first substrate surface and a second substrate surface arranged opposite to the first substrate surface;
a die stack comprising a plurality of dies arranged on the first substrate surface in a first shingle stack configuration, wherein each die of the plurality of dies has an upper die surface with an exposed portion that includes one or more exposed bond pads; and
a redistribution layer (RDL) module stack comprising a plurality of RDL modules arranged on the first substrate surface in a second shingle stack configuration that corresponds to the first shingle stack configuration,
wherein the RDL module stack is configured to electrically couple each die of the plurality of dies to the circuit substrate.

2. The semiconductor device assembly of claim 1, wherein each RDL module of the plurality of RDL modules is a single RDL.

3. The semiconductor device assembly of claim 1, wherein the plurality of dies includes a base die, coupled adjacent to the first substrate surface, and a top die, arranged furthest from the first substrate surface among the plurality of dies, and
wherein the plurality of RDL modules includes a base RDL module, coupled adjacent to the first substrate surface, and a top RDL module, coupled to an upper die surface of the top die.

4. The semiconductor device assembly of claim 3, wherein each RDL module of the plurality of RDL modules, excluding the top RDL module, includes an upper module surface that is substantially planar with an upper die surface of a respective die of the plurality of dies.

5. The semiconductor device assembly of claim 3, wherein each RDL module of the plurality of RDL modules, excluding the base RDL module, is mechanically bonded to an upper die surface of a respective die of the plurality of dies by an electrical interconnect for providing an electrical signal to the respective die.

6. The semiconductor device assembly of claim 1, further comprising:
a plurality of conductive module-to-module interconnects arranged between adjacent RDL modules for mechanical and electrical coupling of the adjacent RDL modules; and
a plurality of conductive module-to-die interconnects for mechanical and electrical coupling of each RDL module of the plurality of RDL modules to a respective die of the plurality of dies.

7. The semiconductor device assembly of claim 6, wherein the plurality of conductive module-to-module interconnects and the plurality of conductive module-to-die interconnects are conductive bumps.

8. The semiconductor device assembly of claim 6, wherein the plurality of conductive module-to-module interconnects and the plurality of conductive module-to-die interconnects are thermocompression interconnects.

9. The semiconductor device assembly of claim 1, wherein each subsequent die of the plurality of dies is laterally offset from a previous die of the plurality of dies such that each exposed portion is exposed for RDL connection, and
wherein each exposed bond pad of the one or more exposed bonds is mechanically and electrically coupled to the RDL module stack.

10. The semiconductor device assembly of claim 9, wherein each subsequent RDL module of the plurality of RDL modules is laterally offset from a previous RDL module of the plurality of RDL modules such that the subsequent RDL module is mechanically and electrically coupled to the one or more exposed bonds of a respective die of the plurality of dies.

11. The semiconductor device assembly of claim 1, wherein each RDL module of the plurality of RDL modules includes one or more conductive paths for transmitting data signals between the circuit substrate and one or more dies of the plurality of dies.

12. The semiconductor device assembly of claim 1, wherein each RDL module of the plurality of RDL modules includes one or more conductive paths for transmitting power signals between the circuit substrate and one or more dies of the plurality of dies.

13. The semiconductor device assembly of claim 1, wherein the plurality of dies is N dies, where N is an integer greater than one,
wherein the plurality of RDL modules is N+1 RDL modules, and
wherein the N+1 RDL modules include:
a base RDL module mechanically and electrically coupled to the first substrate surface; and
two or more subsequent RDL modules respectively coupled to the plurality of dies.

14. The semiconductor device assembly of claim 1, wherein the plurality of dies are memory dies configured to store data according to write operations and output data according to read operations, and
wherein the plurality of RDL modules is configured to transmit input/output (I/O) data signals between the circuit substrate and the plurality of dies according to the write operations and the read operations.

15. The semiconductor device assembly of claim 1, further comprising:
a package casing disposed over the first substrate surface, wherein the package casing encapsulates the plurality of dies and the plurality of RDL modules; and
a plurality of conductive interconnect structures coupled to the second substrate surface, wherein the plurality of conductive interconnect structures are electrically coupled to the plurality of RDL modules by the circuit substrate.

16. A semiconductor device assembly, comprising:
a circuit substrate comprising a first substrate surface and a second substrate surface arranged opposite to the first substrate surface;
a die arranged on the first substrate surface, wherein the die has an upper surface with an edge portion that includes one or more bond pads;
a redistribution layer (RDL) module stack comprising a plurality of RDL modules arranged on the first substrate surface in a shingle stack configuration,
wherein the RDL module stack is configured to electrically couple the die to the circuit substrate, and
wherein the plurality of RDL modules includes an RDL module arranged on the edge portion of the die and coupled to the one or more bond pads;
a package casing disposed over the first substrate surface, wherein the package casing encapsulates the die and the plurality of RDL modules; and
a plurality of conductive interconnect structures coupled to the second substrate surface,
wherein the plurality of conductive interconnect structures are electrically coupled to the plurality of RDL modules by the circuit substrate.

17. The semiconductor device assembly of claim 16, further comprising:
one or more conductive module-to-module interconnects arranged between adjacent RDL modules for mechanical and electrical coupling of the adjacent RDL modules; and
one or more conductive module-to-die interconnects for mechanical and electrical coupling of the RDL module to the one or more bond pads.

18. A semiconductor device assembly, comprising:
a circuit substrate comprising a first substrate surface and a second substrate surface arranged opposite to the first substrate surface;
a first die stack comprising a plurality of first dies arranged over the first substrate surface in a first shingle stack configuration, wherein each first die of the plurality of first dies has a first interconnect side facing the first substrate surface, the first interconnect side comprising one or more first conductive die interconnect structures for being electrically connected to the circuit substrate,
wherein the plurality of first dies includes:
a first base die, electrically coupled to the circuit substrate by a first die-to-substrate interconnection that includes one or more first conductive die interconnect structures of the first base die; and
a first subsequent die arranged on the first base die; and
a redistribution layer (RDL) module arranged over the first substrate surface, wherein the RDL module is coupled to one or more first conductive die interconnect structures of the first subsequent die for electrically coupling the first subsequent die to the circuit substrate.

19. The semiconductor device assembly of claim 18, further comprising:
a second die stack comprising a plurality of second dies arranged over the first substrate surface in a second shingle stack configuration, wherein each second die of the plurality of second dies has a second interconnect side facing the first substrate surface, the second interconnect side comprising one or more second conductive die interconnect structures for being electrically connected to the circuit substrate,
wherein the plurality of second dies includes:
a second base die, electrically coupled to the circuit substrate by a second die-to-substrate interconnection that includes one or more second conductive die interconnect structures of the second base die; and
a second subsequent die arranged on the second base die,
wherein the RDL module is coupled to one or more second conductive die interconnect structures of the second subsequent die for electrically coupling the second subsequent die to the circuit substrate.

20. The semiconductor device assembly of claim 19, wherein the RDL module is a single RDL arranged laterally between the first base die and the second base die.

21. The semiconductor device assembly of claim 19, further comprising:
a plurality of conductive module-to-die interconnects for mechanical and electrical coupling of the RDL module to the one or more first conductive die interconnect structures of the first subsequent die and to the one or more second conductive die interconnect structures of the second subsequent die.

22. The semiconductor device assembly of claim 21, wherein the plurality of conductive module-to-die interconnects are conductive bumps arranged on the RDL module.

23. The semiconductor device assembly of claim 19, wherein the RDL module is electrically coupled to the first base die and the second base die by the circuit substrate.

24. The semiconductor device assembly of claim 23, wherein the plurality of first dies and the plurality of second dies are memory dies configured to store data according to write operations and output data according to read operations, and
wherein the RDL module is configured to transmit input/output (I/O) data signals between the circuit substrate and the plurality of first dies and between the circuit substrate and the plurality of second dies according to the write operations and the read operations.

25. A method of manufacturing a semiconductor device assembly, the method comprising:
arranging a plurality of first dies on a carrier in a first shingle stack configuration, wherein each first die of the plurality of first dies has a first interconnect side facing away from the carrier, the first interconnect side comprising one or more first conductive die interconnect structures;
arranging a plurality of second dies on the carrier in a second shingle stack configuration, wherein each second die of the plurality of second dies has a second interconnect side facing away from the carrier, the second interconnect side comprising one or more second conductive die interconnect structures;
arranging an RDL module on a corresponding first die of the plurality of first dies and on a corresponding second die of the plurality of second dies, wherein the RDL module is electrically coupled to one or more first conductive die interconnect structures of the corresponding first die, and wherein the RDL module is electrically coupled to one or more second conductive die interconnect structures of the corresponding second die;
encapsulating the plurality of first dies, the plurality of second dies, and the RDL module in a package casing, wherein the package casing includes a first side arranged on the carrier and second side opposite to the first side;
removing the carrier; and
coupling the plurality of first dies, the plurality of second dies, and the RDL module to a first substrate surface of a circuit substrate such that the second side of the package casing is coupled to the first substrate surface,
wherein the circuit substrate is electrically coupled to the corresponding second die and the corresponding first die by the RDL module.
